(19) United States
(12) Patent Application Publication
(10) Pub. No.: US 2022/0254799 A1
(43) Pub. Date: Aug. 11, 2022

(54) SEMICONDUCTOR DEVICE AND OPERATION METHOD THEREOF

(71) Applicant: MACRONIX INTERNATIONAL CO., LTD., Hsinchu (TW)

(72) Inventors: Hang-Ting LUE, Zhubei City (TW); Cheng-Lin SUNG, Taichung City (TW); Wei-Chen CHEN, Taoyuan city (TW)

(21) Appl. No.: 17/495,826

(22) Filed: Oct. 7, 2021

Related U.S. Application Data
(60) Provisional application No. 63/145,989, filed on Feb. 5, 2021.

(51) Int. Cl. H01L 27/11556; H01L 27/11582; H01L 27/11519; H01L 27/11565

(52) U.S. Cl. CPC H01L 27/11556; H01L 27/11582; G11C 5/06; H01L 27/11565; H01L 27/11519

(57) ABSTRACT

A semiconductor device is provided. The semiconductor device includes a first vertical stack, a first vertical channel line, a first data storage structure, and a first gate dielectric structure. The first vertical stack includes a first conductive line and a second conductive line. The first vertical channel line vertically passes through the first conductive line and the second conductive line, and the first vertical channel line is a P-type channel. The first data storage structure is disposed between the first conductive line and the first vertical channel line. The first gate dielectric structure is disposed between the second conductive line and the first vertical channel line.

This application claims the benefits of U.S. provisional application Ser. No. 63/145,989, filed Feb. 5, 2021, the subject matters of which is incorporated herein by references.

### BACKGROUND

### Technical Field

The disclosure relates in general to a semiconductor device and an operation method thereof.

### Description of the Related Art

The n-channel flash cell is the most popular one in nonvolatile memories but it has low injection efficiency, large power dissipation, serious disturb, and data retention degradation problems. For flash memory, tunneling leakage or oxide damage is a major concern. This will lead to serious cell reliabilities, such as operation window closure, disturb and reduced ability of data retention. As a consequence, it is still mandatory for us to make effort to improve the reliability problems existing in flash memories.

### SUMMARY

The disclosure is directed to a semiconductor device, for example, a three-dimensional integrated circuit memory structure that has a vertical select transistor and a vertical data storage transistor.

According to one embodiment, a semiconductor device is provided. The semiconductor device includes a first vertical stack, a first vertical channel line, a first data storage structure, and a first gate dielectric structure. The first vertical stack includes a first conductive line and a second conductive line. The first vertical channel line vertically passes through the first conductive line and the second conductive line, and the first vertical channel line is a P-type channel. The first data storage structure is disposed between the first conductive line and the first vertical channel line. The first gate dielectric structure is disposed between the second conductive line and the first vertical channel line.

According to another embodiment, an operating method of the above-mentioned semiconductor device is provided. The method includes: applying a first voltage to a first terminal of the first vertical channel line; applying a second voltage to a second terminal of the first vertical channel line; applying a first control voltage to the first conductive line; and applying a second control voltage to the second conductive line.

### BRIEF DESCRIPTION OF THE DRAWINGS

FIG. 1A illustrates a memory device comprising an array of two-transistor memory cells according to one embodiment.

FIG. 1B illustrates a memory device comprising an array of two-transistor memory cells according to an alternative embodiment.

FIG. 2 illustrates an exemplary two-transistor memory cell suitable for use in an array of two-transistor memory cells.

FIG. 3 illustrates another exemplary two-transistor memory cell.

FIG. 4 is a table illustrating example bias conditions for executing program and erase operations on two-transistor memory cells in accordance with the present disclosure.

FIGS. 5A and 5B are schematic circuit diagrams of a vertical flash array using bias conditions of BBHE electron injection and SSIH hole injection, respectively.

FIGS. 6A and 6B show the BBHE electron injection with various MG and BL biases, respectively.

FIGS. 7A and 7B show the SSIH hole injection with various MG and BL biases, respectively.

FIGS. 8A and 8B illustrate the +FN electron and −FN hole injection characteristics, respectively.

FIGS. 9A and 9B show the result of combination of BBHE electron injection together with −FN hole injection.

FIGS. 10A and 10B respectively show schematic diagrams of P-channel and N-channel memory devices formed on the same substrate.

FIG. 10C is a top view of the memory device of FIG. 10B

FIG. 11 is a simplified block diagram of an integrated circuit according to the present disclosure.

FIG. 12 is a schematic diagram of a functional memory circuit applied to FPAA.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

A detailed description of embodiments of the present disclosure is provided with reference to the Figures. The following description will typically be with reference to specific structural embodiments and methods. It is to be understood that there is no intention to limit the technology to the specifically disclosed embodiments and methods but that the technology may be practiced using other features, elements, methods and embodiments. Preferred embodiments are described to illustrate the present disclosure, not to limit its scope, which is defined by the claims. Those of ordinary skill in the art will recognize a variety of equivalent variations on the description that follows. A detailed description of embodiments of the present disclosure is provided with reference to the Figures. Like elements in various figures are commonly referred to with like reference numerals.

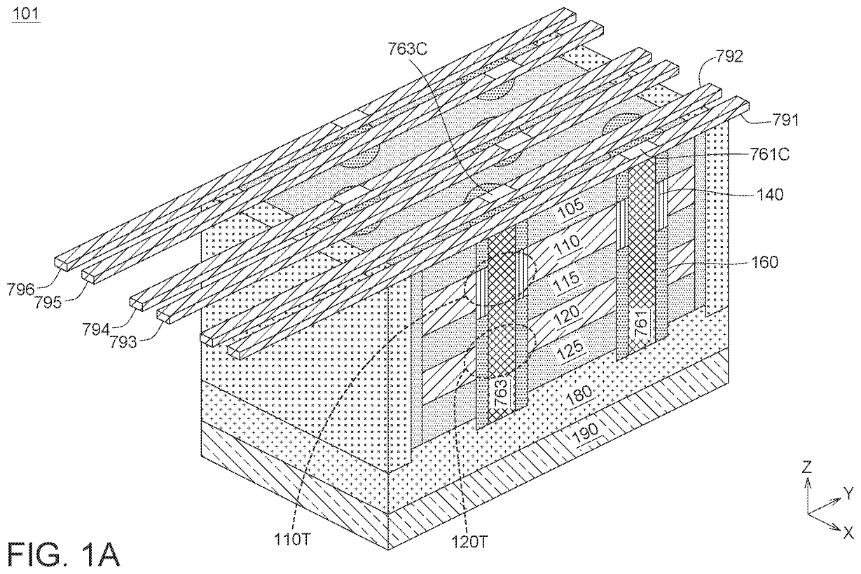

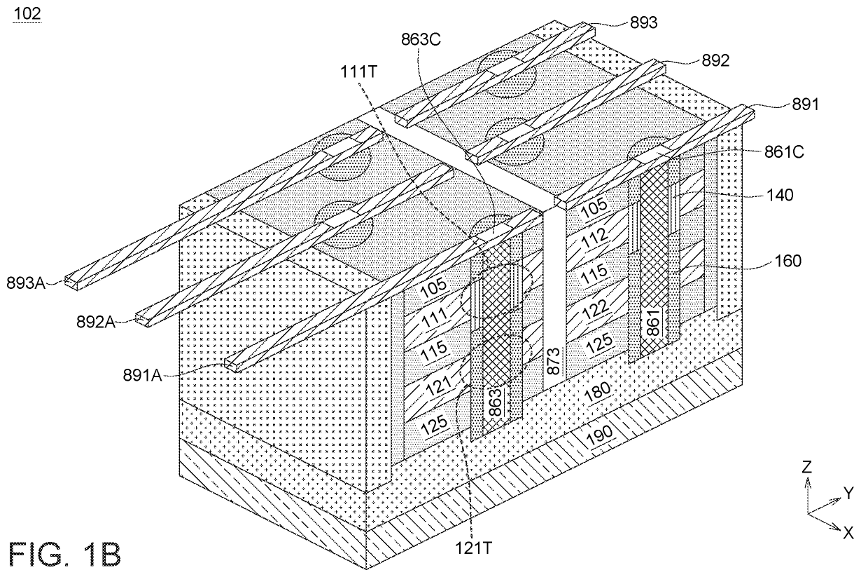

FIG. 1A illustrates a semiconductor device, for example, a memory device comprising an array of two-transistor memory cells 101, the two-transistor memory cells in the array including a vertical select transistor (e.g. 120T) and a vertical data storage transistor (e.g. 110T), according to one embodiment. The array of two-transistor memory cells comprises a plurality of vertical stacks of conductive lines separated by insulating layers (e.g. 105, 115, 125) on a reference line 180 on a substrate 190. A stack of conductive lines in the plurality of vertical stacks includes a first conductive line (e.g. word line 110) and a second conductive line (e.g. select gate line 120) adjacent the word line 110. In one embodiment, the word line 110 can be above the select gate line 120. In an alternative embodiment, the word line 110 can be beneath the select gate line 120 so that the vertical data storage transistor 110T can be beneath the vertical select transistor 120T.

Referring to FIG. 1A, the memory device includes an array of vertical channel lines (e.g. 761, 763) disposed in vias or holes through the conductive lines in the plurality of vertical stacks to the reference line 180. A two-transistor memory cell suitable for use in the array of two-transistor memory cells 101, including a gate dielectric structure 160 and a data storage structure 140. The gate dielectric structure 160 is located between the select gate line 120 and the vertical channel line, and the data storage structure 140 is located between the word line 110 and the vertical channel line. In this embodiment, the vertical channel lines 761 and 763 are, for example, P-type channels. In other words, the memory device of the present embodiment is composed of two-transistor memory cells whose vertical channel lines 761 and 763 are P-type channel. P-type channel refers to a channel for P-Channel device, which is made of un-doped or lightly N-doped semiconductor material, and the Source/Drain region is P-type doped. The P-Type channel will be formed during the MOS transistor is “on”.

In addition, referring to FIG. 1A, the memory device includes a plurality of bit lines (e.g. 791, 792, 793, 794, 795, 796) overlying the array of vertical channel lines (e.g. 761, 763) and coupled to the vertical channel lines via upper ends of the vertical channel lines. The bit lines (e.g. 791, 792) are coupled to respective vertical channel lines (e.g. 761, 763) of the cells in one-column via respective contacts 761C and 763C.

FIG. 1B illustrates a semiconductor device, such as a memory device comprising an array of two-transistor memory cells 102, the two-transistor memory cells in the array including a vertical select transistor (e.g. 121T) and a vertical data storage transistor (e.g. 111T), according to an alternative embodiment. The array of two-transistor memory cells 102 comprises a plurality of vertical stacks of conductive lines separated by insulating layers (e.g. 105, 115, 125) on a reference line 180 on a substrate 190. A first stack of conductive lines in the plurality of vertical stacks includes a first conductive line (e.g. select gate line 121) and a second conductive line (e.g. word line 111) adjacent the select gate line 121. In one embodiment, the word line 111 can be above the select gate line 121. In an alternative embodiment, the word line 111 can be beneath the select gate line 121 so that the vertical data storage transistor 111T can be beneath the vertical select transistor 121T.

In this embodiment, a second stack of conductive lines in the plurality of vertical stacks includes a third conductive line (e.g. word line 112) and a fourth conductive line (e.g. select gate line 122) adjacent the word line 112. The first stack of conductive lines is electrically isolated from the second stack of conductive lines by an isolation structure 873.

Referring to FIG. 1B, the memory device includes an array of vertical channel lines (e.g. 861, 863) disposed in vias or holes through the conductive lines in the plurality of stacks to the reference line 180. The two-transistor memory cell suitable for use in an array of two-transistor memory cells 102, including a gate dielectric structure 160 and a data storage structure 140. The gate dielectric structure 160 is located between the select gate line 121 (122) and the vertical channel line, and the data storage structure 140 is located between the word line 111 (112) and the vertical channel line. In this embodiment, the vertical channel lines 861 and 863 are, for example, P-type channels. In other words, the memory device of the present embodiment is composed of two-transistor memory cells whose vertical channel lines 861 and 863 are P-type channel.

Referring to FIG. 1B, the memory device includes a plurality of first bit lines (e.g. 891, 892, 893) overlying the array of vertical channel lines (e.g. 861,) and coupled to the vertical channel lines via respective contacts 861C on the upper ends of the vertical channel lines, and a plurality of second bit lines (e.g. 891A, 892A, 893A) overlying the array of vertical channel lines (e.g. 861,) and coupled to the vertical channel lines via respective contacts 863C on the upper ends of the vertical channel lines. The first bit lines (e.g. 891, 892, 893) is separated from the second bit lines (e.g. 891A, 892A, 893A).

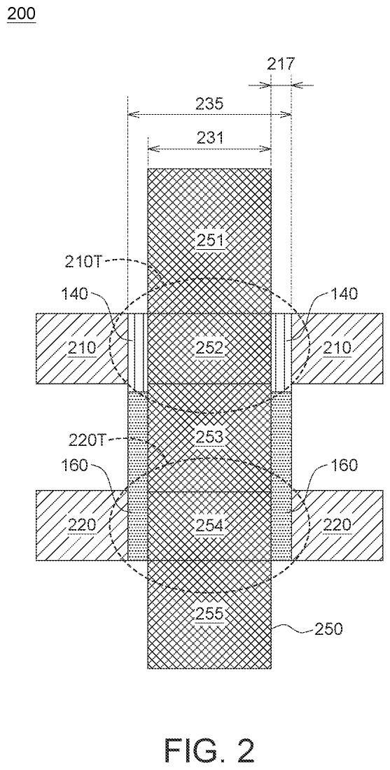

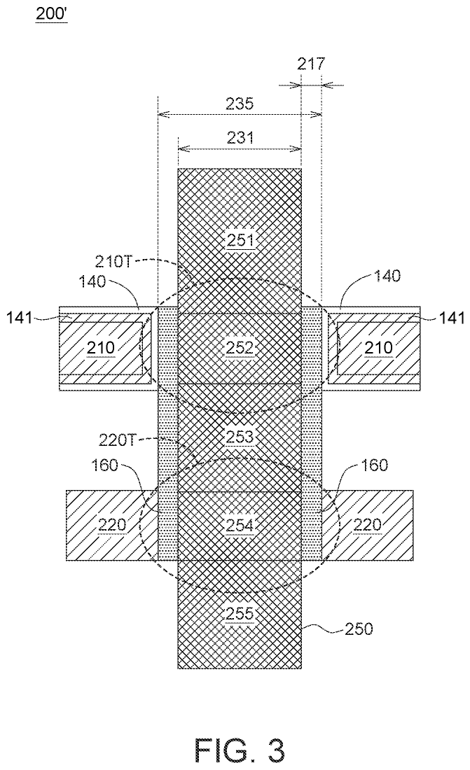

FIG. 2 illustrates a cross section of an example of P-type or N-type channel two-transistor memory cell 200 suitable for use in an array of two-transistor memory cells. FIG. 3 illustrates another exemplary two-transistor memory cell 200′. The two-transistor memory cell 200, 200′ includes a vertical data storage transistor 210T having a first channel region 252 in a vertical channel line 250, and a vertical select transistor 220T having a second channel region 254 in the vertical channel line 250.

The vertical channel line 250 has a first terminal (e.g. top region 251) above the first channel region 252, and a second terminal (e.g. a bottom region 255) below the second channel region 254. The vertical channel line 250 has an intermediate region 253 between the first channel region 252 and the second channel region 254. A bit line (e.g. 791, FIG. 1A) can be coupled to the top region 251 of the vertical channel line 250. A reference line (e.g. 180, FIG. 1A) can be coupled to the bottom region 255 of the vertical channel line 250. A select gate line 220 surrounds the second channel region 254 in the vertical channel line 250, and a gate dielectric structure 160 is disposed between the select gate line 220 and the second channel region 254 in the vertical channel line 250. In FIG. 3, the gate dielectric structure 160 further extend upward and between the word line 210 and the first channel region 252 in the vertical channel line 250.

In addition, the word line 210 surrounds the first channel region 252 in the vertical channel line 250, and a data storage structure 140 is disposed on side surfaces of the word line 210, and between the word line 210 and the first channel region 252 in the vertical channel line 250. In FIG. 3, the data storage structure 140 is disposed between the word line 210 and the first channel region 252 in the vertical channel line 250, between the word line 210 and the upper insulating layer (e.g. 105), and between the word line 210 and the lower insulating layer (e.g. 115).

In one embodiment, the first channel region 252 of the vertical data storage transistor 210T in the vertical channel line 250 can have a channel length of about 20 nm to 60 nm (nm=nanometer) determined by a thickness of the word line 210, and the second channel region 254 of the vertical select transistor 220T in the vertical channel line 250 can have a channel length of about 20 nm to 60 nm determined by a thickness of the select gate line 220. The vertical channel line 250 can have a channel diameter 231 of about 50 nm to 90 nm. The gate dielectric structure 160 disposed between the vertical channel line 250 and the select gate line 220 can have a dielectric thickness 217 of about 2 nm to 3 nm. A channel hole diameter 235 is equal to the channel diameter 231 plus twice the dielectric thickness 217.

In one embodiment, the data storage structure 140 disposed between the vertical channel line 250 and the word line 210 can include charge trapping layers having Oxide/Nitride/Oxide, or floating gate layers having oxide/poly silicon/oxide. A blocking layer, for example a high-k liner 141, can be formed between the multilayer data storage structure 140 and the word line 210 and in contact with the word line 210 or around the word line 210. The high-k liner 141 can include Al₂O₃ with a thickness of about 3 nm for example.

In addition, the first and second channel regions 252 and 254 in the vertical channel line 250 can include undoped polysilicon or single-crystal Si with a selective epitaxy growth channel, which has much better read current and Vt distribution than the polysilicon channel. In the two-transistor memory cell 200 whose vertical channel line is a P-type channel, the top region 251 and the bottom region 255 are, for example, p-type doped regions in N-type well.

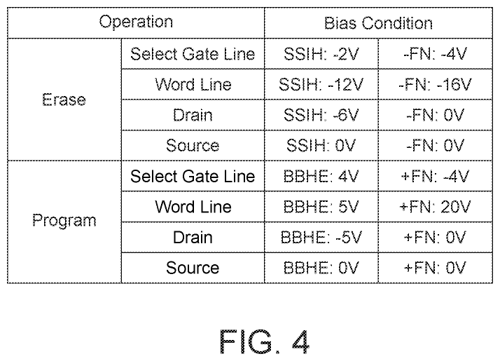

FIG. 4 is a table illustrating example bias conditions for executing program and erase operations on P-type channel two-transistor memory cells in accordance with the present disclosure. Two-transistor memory cells in the array of two-transistor memory cells include a vertical select transistor (e.g. 220T, FIG. 2) and a vertical data storage transistor (e.g. 210T, FIG. 2). “Select Gate Line” and “Word Line” as used in the table are illustrated in FIG. 2. “Drain” and “Source” as used in the table can be illustrated in FIG. 2 by a top region 251 and a bottom region 255, respectively. For an erase operation in the table, “−FN” refers to Fowler-Nordheim hole tunneling injection, and SSIH refers to source-side injection hot hole. For a program operation in the table, BBHE refers to band-to-band tunneling-induced hot-electron injection, and “+FN” refers to Fowler-Nordheim electron injection.

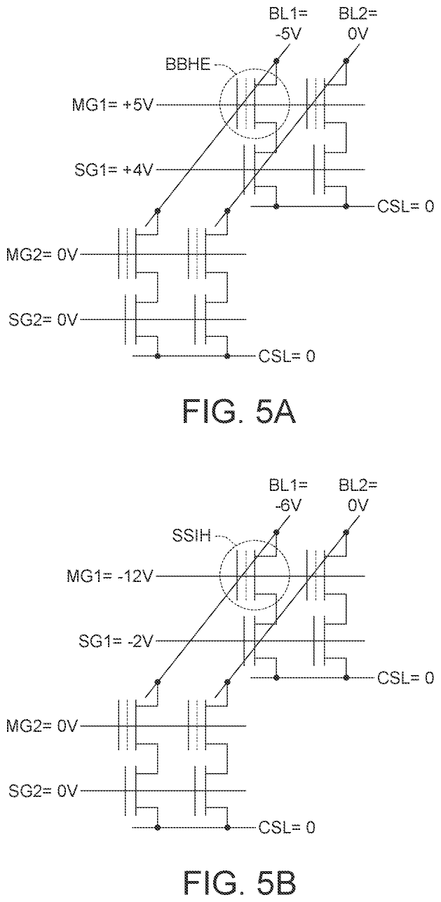

FIGS. 5A and 5B are schematic circuit diagrams of a flash array using two-transistor memory cells as described herein. In the illustration, there are four two-transistor memory cells. Each cell includes a select gate transistor (e.g. SG1, SG2) in series with a data storage transistor (e.g. MG1, MG2). The cells are disposed between bit lines BL1 and BL2, and one or more common source lines CSL. In one embodiment, referring to FIG. 5A, an operating method of the semiconductor device includes: applying a first voltage (e.g. BL1=−5V) to a first terminal of the first vertical channel line; applying a second voltage (e.g. CSL=0V) to a second terminal of the first vertical channel line; applying a first control voltage (e.g. MG1=+5V) to the first conductive line; and applying a second control voltage (e.g. SG1=+4V) to the second conductive line.

For a SSIH erase operation in FIG. 5B, the select gate line for unselected cells can be biased at 0 V and left in a non-conducting off condition. The select gate line for selected cells can be biased at −2 Volts (second control voltage). The word line of the selected cell can be biased at a voltage on the order of −12 Volts (first control voltage). The unselected word line can be left at 0 V. The bit line on the selected cell can be biased at −6 V (first voltage), while the bit line on the unselected cells can be biased at 0 V, for example. The common source line can likewise be left at 0 V (second voltage). This program bias will induce the selected memory cell to be programmed to a low Vt threshold, which can be less than 0 V.

For a BBHE program operation in FIG. 5A, the word lines in the selected block can be biased at about +5 V (first control voltage), while the bit lines in the selected block can be biased at about −5 V (first voltage). The select gate line can be biased at about +4 V (second control voltage) so that they remain off during the operation. Also, the common source lines can be biased at about 0 V (second voltage). This applied electric field will induce a high threshold erase state.

Because of the select gate in the flash array of two-transistor memory cells, over-program or over-erase conditions do not cause leakage or other types of operational problems. This reduces the complexity in the program and erase algorithms required for operation of the array.

The feature of p-channel two-transistor memory cells is that it has many operation methods to write and erase. For example, in the program operation of FIG. 4, BBHE or +FN electron injection bias conditions are used, and in the erase operation of FIG. 4, SSIH or −FN hole injection bias conditions are used. In addition, Bit-alterable selection method is possible. FIGS. 5A and 5B illustrate the selection method for BBHE and SSIH, respectively. Both +FN and −FN also has the possibility of selection, but the operating bias is much larger.

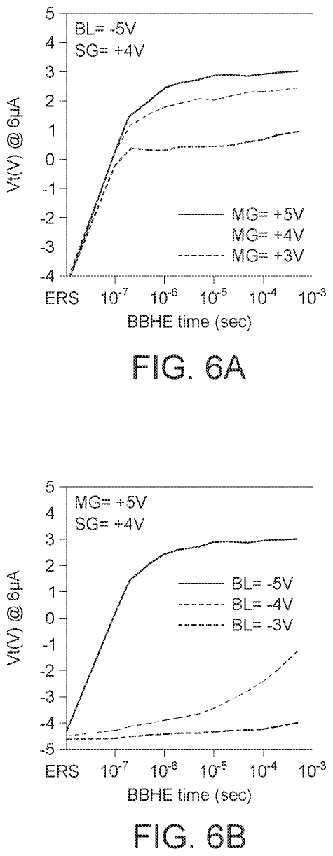

FIGS. 6A and 6B show the BBHE electron injection with various MG and BL biases, respectively. Both MG and SG transistor memory cells are positive to turn-off the channel, while the bit line (BL) is applied −5V. It is found that BBHE electron injection is sensitively dependent on the MG and BL biases. It needs a higher BL bias (less than −5V) and MG bias (more than +5V) to generate BBHE. Injection speed of BBHE is pretty fast. It can achieve threshold voltage (Vt) memory window shift (more than 6V) at less than 1 μsec.

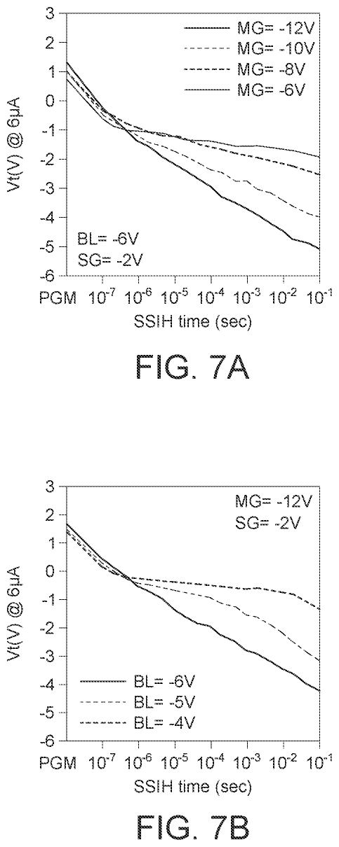

FIGS. 7A and 7B show the SSIH hole injection with various MG and BL biases, respectively. Both MG and SG transistor memory cells are negative to turn-on the channel, while BL is applied −6V. For faster SSIH speed, it needs a higher BL bias (less than −6V) and MG bias (less than −12V) to generate SSIH with Vt memory window shift (more than 6V) within 100 msec.

As shown in electron and hole injection profiles simulated by the Technology Computer Aided Design (TCAD) for BBHE and SSIH. BBHE tends to inject electrons near the top junction edge of MG transistor memory cell, while SSIH tends to inject holes near the junction between MG and SG transistor memory cells.

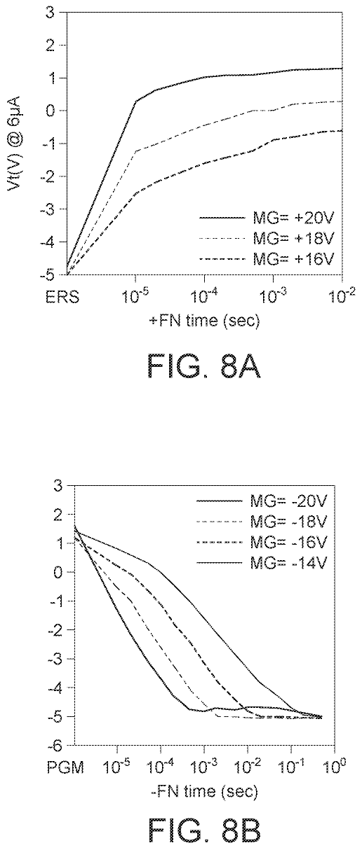

FIGS. 8A and 8B illustrate the +FN electron and −FN hole injection characteristics, respectively. +FN electron injection can get fast initial programming within 10 μsec, but it easily saturates. −FN hole injection can reach Vt less than −5V within 1 msec at the MG bias of −20 V. It is comparable with the ordinary BE-MANOS (Meta/Al₂O₃/SiN/SiO₂/Si) charge-trapping device of 3D NAND memory. It should be mentioned that hole is easily generated at p-channel device since the P+ junction directly offer hole sources during −FN. However, electron source is limited in p-channel device since both junctions are P+. This may give rise to limit+FN electron injection performances.

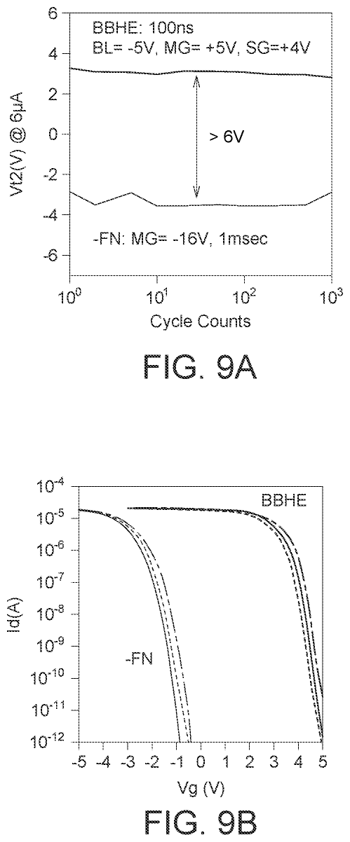

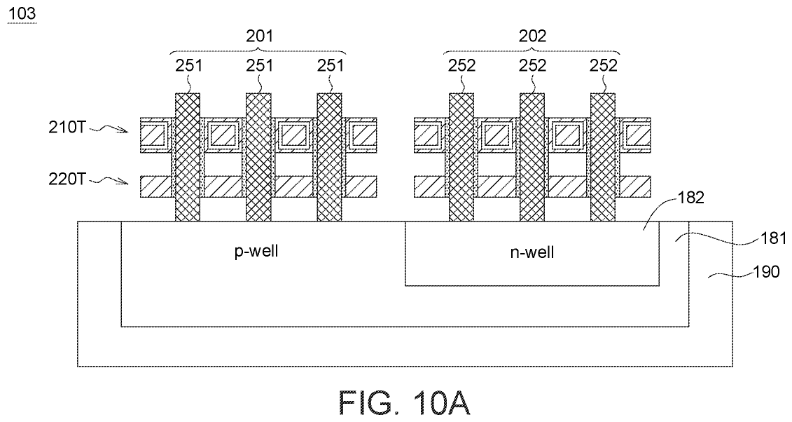

Referring to FIGS. 9A and 9B, in one the embodiment, it is found that the combination of BBHE electron injection together with −FN hole injection shows the good match to produce better endurance. In FIG. 9A, Vt memory window more than 6V during 1K cycling is obtained. BBHE programming pulse keeps at 100 ns only, while −FN erasing keeps at 1 msec. In FIG. 9B, the corresponding current vs. voltage (Id/Vg) curves are excellent during cycling. It is shown that the post-1K cycled retention measured at 85 C. a reasonable data retention performance is obtained such that cell performance and reliability of data retention can be largely improved.

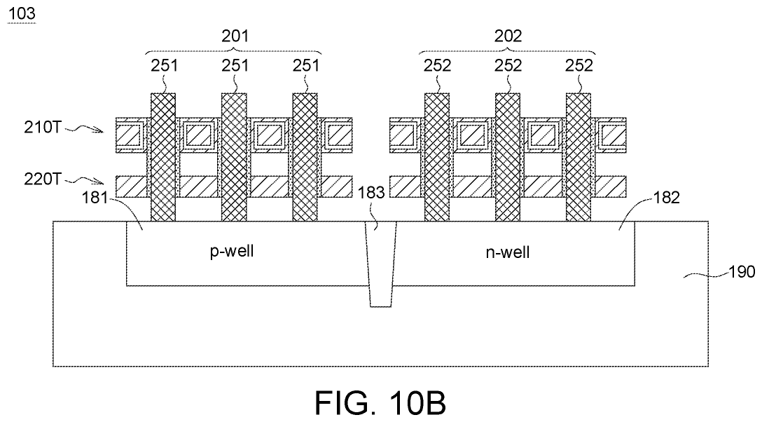

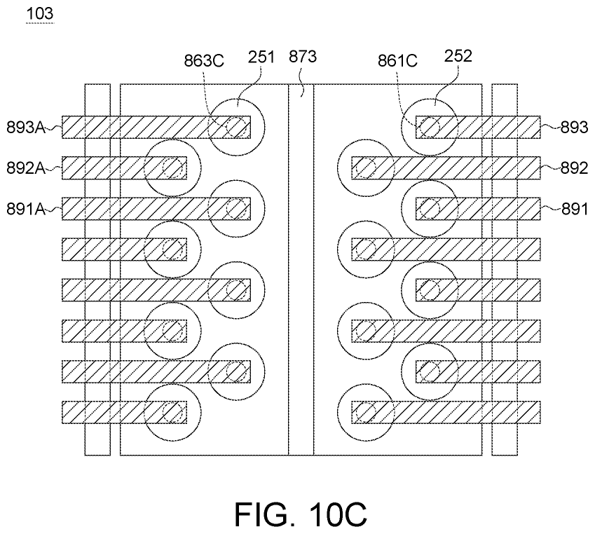

FIGS. 10A and 10B show schematic diagrams of the CMOS device of P-type channel and N-type channel formed on the same substrate, respectively, and FIG. 10C is a top view of the CMOS device of FIG. 10B. In FIG. 10A, the CMOS device includes a plurality of vertical channel lines, namely p-type channels and N-type channels, where the two-transistor memory cells 201 whose the vertical channel line is P-type channel 251 are electrically connected to the P-type well (or P-type polysilicon) 181 of a substrate 190, and the two-transistor memory cells 202 whose vertical channel line is N-type channel 252 are electrically connected to the N-type well (or N-type polysilicon) 182 of the same substrate. Therefore, P-type channel and N-type channel memory devices can be formed on the same substrate 190. In other embodiments, the P-type channel 251 may be formed on one of the P-type well and N-type well regions, and the N-type channel 252 may be formed on another one of the P-type well and N-type well regions.

In FIG. 10A, in one of the embodiments, the P-type well 181 is overlapped with the N-type well 182. For example, the N-type well is located in the P-type well region, or the P-type well is located in the N-type well region. In FIG. 10B, another one of the embodiments, the P-type well 181 and the N-type well 182 are electrically isolated by, for example, an isolation structure 183.

In FIG. 10C, a plurality of first bit lines (e.g. 891, 892, 893) and a plurality of second bit lines (e.g. 891A, 892A, 893A) are respectively coupled to the corresponding vertical channel lines through the respective contacts 861C, 863C on the upper end of the vertical channel lines. The first bit lines and the second bit lines are separated from each other, the first bit line is connected to the N-type channel 252, and the second bit line is connected to the P-type channel 251.

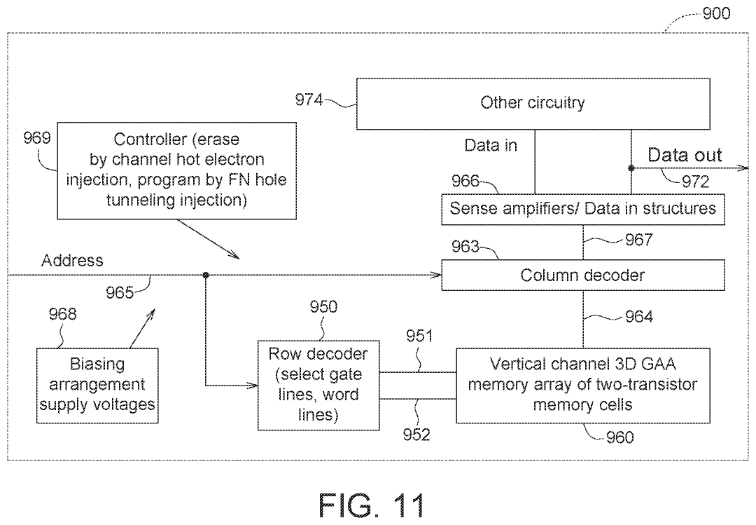

FIG. 11 is a simplified block diagram of an integrated circuit in accordance with the present disclosure. In the example shown in FIG. 11, the integrated circuit 900 includes a vertical channel GAA (gate-all-around) array 960 of two-transistor memory cells, two-transistor memory cells in the array including a vertical select transistor and a vertical data storage transistor. The array 960 of two-transistor memory cells comprises a plurality of vertical stacks of conductive lines separated by insulating layers on a substrate, a stack of conductive lines in the plurality of stacks including a select gate line and a word line adjacent the select gate line.

The array 960 comprises an array of vertical channel lines, for example, a P-type channel and/or N-type channel, disposed through the conductive lines in the plurality of vertical stacks to a reference line, gate dielectric structures surrounding the vertical channel lines at channel regions of vertical select transistors in the array of vertical channel lines and the select gate lines, data storage structures surrounding the vertical channel lines at channel regions of vertical data storage transistors in the array of vertical channel lines and the word lines, and a plurality of bit lines overlying the array of vertical channel lines and coupled to the vertical channel lines via upper ends of the vertical channel lines.

A row decoder 950 is coupled to a plurality of select gate lines 951 and a plurality of word lines 952, and arranged along rows in the memory array 960. A column decoder 963 is coupled to a plurality of bit lines 964 arranged along columns in the memory array 960 for reading and programming data from the memory cells in the memory array 960. Addresses are supplied on bus 965 to column decoder 963 and row decoder 961. Sense amplifiers and data-in structures in block 966 are coupled to the column decoder 963 in this example via data bus 967. Data is supplied via the data-in line 971 from input/output ports on the integrated circuit 900 or from other data sources internal or external to the integrated circuit 900, to the data-in structures in block 966. In the illustrated embodiment, other circuitry 974 is included on the integrated circuit, such as a general purpose processor or special purpose application circuitry, or a combination of modules providing system-on-a-chip functionality supported by the programmable resistance cell array. Data is supplied via the data-out line 972 from the sense amplifiers in block 966 to input/output ports on the integrated circuit 900, or to other data destinations internal or external to the integrated circuit 900.

A controller 969 implemented in this example using bias arrangement state machine controls the application of bias arrangement supply voltage generated or provided through the voltage supply or supplies in block 968, such as read, program and erase voltages. For N-type channels, the controller 969 can be configured to execute a program operation on memory cells in the array of two-transistor memory cells by using channel hot electron injection, and to execute an erase operation on memory cells in the array of two-transistor memory cells by using Fowler-Nordheim (FN) or band-to-band hole tunneling injection. For P-type channels, the controller 969 can be configured to execute an erase operation on memory cells in the array of two-transistor memory cells by using tunneling hot hole injection, and to execute a program operation on memory cells in the array of two-transistor memory cells by using Fowler-Nordheim (FN) or band-to-band tunneling-induced hot electron injection.

The controller 969 can be implemented using special-purpose logic circuitry as known in the art. In alternative embodiments, the controller comprises a general-purpose processor, which can be implemented on the same integrated circuit, which executes a computer program to control the operations of the device. In yet other embodiments, a combination of special-purpose logic circuitry and a general-purpose processor can be utilized for implementation of the controller.

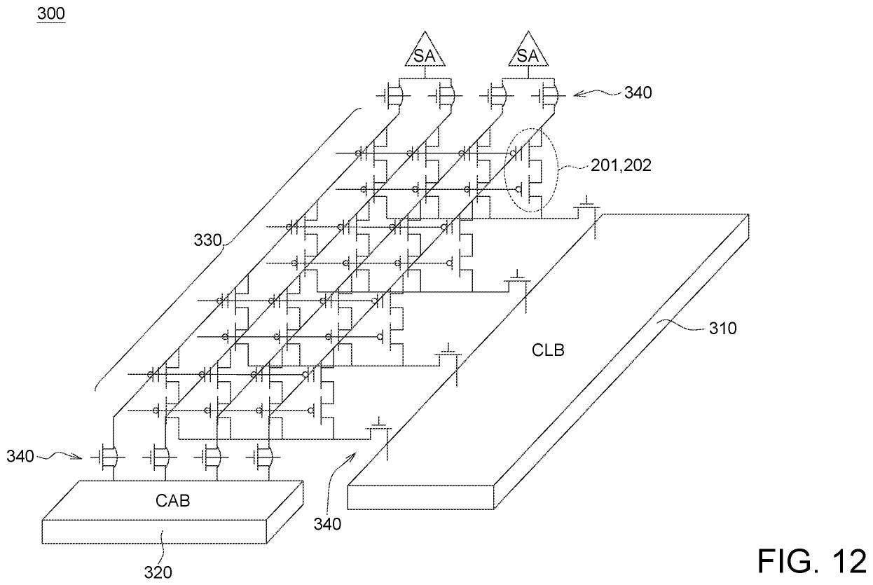

Referring to FIG. 12, which shows a schematic diagram of a functional memory circuit 300 applied to FPAA and can be connected to a sense amplifier (SA) to achieve the effect of low power consumption and low cost connection block. In analog circuit designs, it usually needs to fine tune threshold voltage for adjusting the gain of operational amplifier or controlling operating power. The programmable parameters also benefit for switching frequency, controlling voltage reference, and tuning accuracy of the output voltage regulation in low-power mixed-signal designs. In this embodiment, the vertical p-channel and n-channel two-transistor memory cells 201, 202 can be considered as a promising candidate for various applications due to its ability to support the tunable Vt for either NMOS or PMOS on the same wafer, as shown in FIGS. 10A and 10B, to realize low power consumption and low cost connection block.

For example, configurable circuits, such as field programmable gate arrays (FPGAs) and field programmable analog arrays (FPAAs) become more important for artificial intelligence (AI) applications. Such configurable circuits are constructed by four major parts: computational logic block (CLB) 310, computational analog block (CAB) 320, connection block (CB) 330, and switch block (SB) 340. Among all functional blocks, the CB plays the central role for enabling the flexibility of reconfigurable interconnects for users. The CB conventionally needs 6T SRAM (Static Random Access Memory) to storage the state of interconnection between computational blocks with high on/off ratio. Thus, the use of massive transistors for programmable interconnection in switch matrix accounts for 50%-90% of the total FPGA area and causes high costs. On the other hand, vertical channel two-transistor memory cells 201, 202 can provide on/off ratio higher than 7 orders to increase the signal-to-noise ratio and act as high density memory array to offer more complicated routing at low costs. Besides, it will be energy efficiency for using vertical channel two-transistor memory cells because the information can be retained without refresh. Therefore, it has high potential of realizing analog system design or the routing in FPAA or FPGA architectures using vertical channel two-transistor memory cells 201, 202.

In view of the above embodiments of disclosure, a semiconductor device, for example, a three-dimensional integrated circuit memory structure that has a smaller memory cell size and can operate under a lower bias voltage is provided, such as a novel vertical p-channel and/or n-channel two-transistor memory device. Four different carrier injection modes, including BBHE, +FN, SSIH, and −FN, can be realized in the vertical p-channel and/or n-channel two-transistor memory device for program and erase. With advantages of programmability, high on/off ratio, reasonable retention, and easy fabrication of n-channel and p-channel in same wafer, the vertical p-channel and/or n-channel two-transistor memory device have high potential of enabling functional memory circuits such as re-configurable switch in FPAA.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor device, comprising:
a first vertical stack comprising a first conductive line and a second conductive line;
a first vertical channel line penetrating vertically through the first conductive line and the second conductive line, and the first vertical channel line being a P-type channel;
a first data storage structure disposed between the first conductive line and the first vertical channel line; and
a first gate dielectric structure disposed between the second conductive line and the first vertical channel line.

2. The semiconductor device according to claim 1, further comprising a substrate, wherein the first vertical channel line comprises a first terminal and a second terminal, and the first terminal and the second terminal are respectively P-type doped regions, and the second terminal is electrically connected to a P-type well of the substrate below the first vertical stack.

3. The semiconductor device according to claim 1, wherein the first conductive line is a word line, and the second conductive line is a select gate line.

4. The semiconductor device according to claim 1, wherein the first vertical stack comprises an upper insulating layer, a lower insulating layer, a data storage structure, wherein the first conductive line is located between the upper insulating layer and the lower insulating layer, the data storage structure is disposed between the first conductive line and the vertical channel line, between the first conductive line and the upper insulating layer, and between the first conductive line and the lower insulating layer.

5. The semiconductor device according to claim 4, wherein the first vertical stack further comprises a blocking layer disposed around the first conductive line.

6. The semiconductor device according to claim 1, further comprising:
a second vertical stack, including a third conductive line and a fourth conductive line;
a second vertical channel line vertically penetrating through the third conductive line and the fourth conductive line, and the second vertical channel line being an N-type channel;
a second data storage structure disposed between the third conductive line and the second vertical channel line; and
a second gate dielectric structure disposed between the fourth conductive line and the second vertical channel line.

7. The semiconductor device according to claim 6, further comprising a substrate having a P-type well and a N-type well, the first vertical channel is electrically connected to one of the P-type well and the N-type well, and the second vertical channel is electrically connected to another one of the P-type well and the N-type well.

8. The semiconductor device according to claim 6, further comprising a substrate having a P-type polysilicon and a N-type polysilicon, the first vertical channel is electrically connected to one of the P-type polysilicon and the N-type polysilicon, and the second vertical channel is electrically connected to another one of the P-type polysilicon and the N-type polysilicon.

9. The semiconductor device according to claim 6, wherein the semiconductor device is a CMOS device composed of a two-transistor memory cell having the P-type channel and a two-transistor memory cell having the N-type channel.

10. The semiconductor device according to claim 9, wherein the memory device performs a write operation and an erase operation of the two-transistor memory cells having the P-type channel and the N-type channel by a controller.

11. The semiconductor device according to claim 9, wherein the memory device is used as a functional memory circuit of field programmable gate arrays (FPGAs).

12. An operating method for the semiconductor device of claim 1, comprising:
applying a first voltage to a first terminal of the first vertical channel line;
applying a second voltage to a second terminal of the first vertical channel line;
applying a first control voltage to the first conductive line; and
applying a second control voltage to the second conductive line.

13. The operation method according to claim 12, wherein the operation method uses Fowler-Nordheim (FN) electron injection.

14. The operation method according to claim 12, wherein the operation method uses Fowler-Nordheim (FN) hole tunneling injection.

15. The operation method according to claim 12, wherein the operation method uses band-to-band tunneling-induced hot electron injection.

16. The operation method according to claim 12, wherein the operation method uses source-side injection hot-hole.
